(19) United States
(12) Patent Application Publication
(10) Pub. No.: US 2011/0089931 A1
(43) Pub. Date: Apr. 21, 2011

(54) TEMPERATURE-COMPENSATED SHUNT CURRENT MEASUREMENT

(75) Inventors: Ilia PODLISK, Carmiel (IL); George RUCAREANU, Nesher (IL)

(73) Assignee: Nemic-Lambda Ltd., Carmiel (IL)

(21) Appl. No.: 12/581,300

(22) Filed: Oct. 19, 2009

(51) Int. Cl. G01R 1/20

(52) U.S. Cl. 324/126

(57) ABSTRACT

A current sensor includes a shunt and at least one resistant element. The shunt conveys an electric current, and has a resistance which varies with the shunt's temperature. A resistant element, which has a resistance that varies with its own temperature, is electrically connected between the shunt and an output terminal of the current sensor. At least a portion of the resistant element is in thermal contact with a predetermined location on the shunt, so that the resistant element's resistance varies in accordance with the shunt temperature. The current sensor may be connected to an amplifier whose gain varies in accordance with the resistance of the resistant element. The variation in the resistance of the resistant element causes a change in the amplifier gain, which compensates for changes in the shunt resistance due to change's in the shunt's temperature. In some embodiments, a second resistant element is connected between the shunt and a second output terminal.

### FIELD AND BACKGROUND OF THE INVENTION

The present invention, in some embodiments thereof, relates to a shunt with a temperature-sensitive resistant element, and more particularly, but not exclusively, relates to current measurement through a shunt with compensation for temperature-related resistance changes.

Current measurement is often performed by placing a current shunt in the current pathway. The voltage drop across the shunt is measured, and the current calculated by dividing the voltage by the resistance of the shunt.

In order to accurate results, the resistance of the current shunt between the sensing points must be known with high accuracy. The resistance of many materials suffers from a large change in resistance due to changes in temperature. Therefore a significant current measurement error occurs if a fixed value for resistance is used in the calculation of the current through such a shunt.

This effect is sometimes overcome by using a more expensive material such as Manganin, since Manganin has a smaller change in resistance with temperature. However, even with shunts made of Manganin, portions of the shunt which are made of different materials (such as brass) may still cause significant temperature-related changes in resistance.

In U.S. Pat. No. 6,677,850 by Dames, an electrical current sensor includes a it resistor shunt configuration, wherein the resistors comprise layered conductors at substantially equal temperatures to provide a zero temperature coefficient sensor.

In U.S. Pat. No. 6,028,426 by Cameron et al., an apparatus and method for measuring electric current includes a conductive shunt for developing a voltage drop in response to current flow through the shunt, an amplifier for amplifying the voltage drop across the shunt, a temperature sensor for sensing the temperature of the shunt and controlling the gain of an adjustable attenuator for temperature compensation.

In European Pat. 0161477, an electronic energy consumption meter includes a device for generating a voltage signal proportional to the user current. The device for generating the voltage signal proportional to the current use is a shunt resistance or shunt between phase entry and exit. The phase entry is connected with the first input of an operational amplifier. A measuring resistance is connected between the phase output and the second input of the operational amplifier. The shunt resistance and the measuring resistance are coupled with one another thermally closely so that the measuring resistance on temperature changes in percentage terms evenly as does the shunt resistance.

Additional background art includes German Pat. Appl. 10211117.

### SUMMARY OF THE INVENTION

Some embodiments of the present invention relates to measuring the current through a shunt by the voltage drop over the shunt (also denoted herein the shunt voltage). Variations in the voltage drop over the shunt due to temperature-related changes in the shunt resistance are compensated for by using an amplifier which has a gain which varies in accordance with the shunt temperature. The gain variation is created by including a resistant element in the amplifier circuit, which has a resistance which varies in accordance with the shunt temperature. In some embodiments the resistant element includes a thermistor which is affixed to (or located in proximity to) the shunt, so that the thermistor's temperature is close to or equals the shunt temperature. Changes in the shunt temperature change the total resistance of the amplifier input path, ultimately resulting in a change in amplifier gain. The resistant element's properties are selected so that the amplifier gain adjusts along with the changes in the shunt voltage drop, and provides an essentially constant output level over different temperatures.

According to an aspect of some embodiments of the present invention there is provided a current sensor which includes:

a shunt, configured for conveying an electric current, and having a resistance which varies with a temperature of the shunt;

a first resistant element connected between the shunt and a first output terminal, at least a portion of the first resistant element being in thermal contact with a first predetermined location subject to thermal drift on the shunt, and having a resistance which varies in accordance with a temperature of the shunt, such that a change in the resistance of the shunt causes a compensating change in the gain of an associated amplifier; and

a second output terminal, the first and second output terminals being configured for measurement of a voltage over the shunt.

According to some embodiments of the invention, the first resistant element includes a first fixed resistor and a first thermistor in series.

According to some embodiments of the invention, a reference resistance of the first thermistor equals the product of the total resistance between the shunt and an amplifier input at a reference temperature, and the ratio of the temperature coefficient between the first and second output terminals and the temperature coefficient of the thermistor.

According to some embodiments of the invention, the resistive properties of the first thermistor are selected so as yield an essentially constant output level from an amplifier circuit connected across the shunt output terminals, for an equal current through the shunt over a temperature range.

According to some embodiments of the invention, the resistive properties of the first thermistor are selected so as yield an essentially constant output level from an amplifier circuit connected across the shunt terminals, for an equal current through the shunt for at least two specified temperatures.

According to some embodiments of the invention, the current sensor further includes a second resistant element connected between the shunt and the second terminal, at least a portion of the second resistant element being in thermal contact with a second predetermined location subject to thermal drift on the shunt, and having a resistance which varies in accordance with a temperature of the shunt.

According to some embodiments of the invention, the second resistant element includes a second fixed resistor and a second thermistor in series.

According to some embodiments of the invention, the first predetermined location is located on a shunt mounting.

According to some embodiments of the invention, the resistive properties of the first resistive element include at least one of: a reference resistance, a temperature coefficient of the thermistor, and a value of the fixed resistor.

According to an aspect of some embodiments of the present invention there is provided a current measurement unit, for providing an output for measuring the current through a shunt, wherein the shunt has a resistance which varies with a temperature of the shunt, which includes:

an amplifier, configured for amplifying a voltage drop across the shunt, and having a gain determined by a total resistance between the shunt and the amplifier; and

a first resistant element connected between the shunt and a first amplifier input, in thermal contact with a first predetermined location subject to thermal drift on the shunt, and having a resistance which varies in accordance with the temperature of the shunt, such that a change in shunt resistance causes a compensating change in amplifier gain.

According to some embodiments of the invention, the current measurement unit includes a second resistant element connected between the shunt and a second amplifier input, in thermal contact with a second predetermined location subject to thermal drift on the shunt, wherein a resistance of the second resistant element varies in accordance with the temperature of the shunt.

According to some embodiments of the invention, the first resistant element includes a thermistor, and may further include a fixed resistor.

According to some embodiments of the invention, the first predetermined location is located on a shunt mounting.

According to some embodiments of the invention, the resistive properties of the first resistant element yield an essentially constant amplifier output level for an equal current through the shunt for at least two specified temperatures.

According to some embodiments of the invention, the resistive properties include at least one of a reference resistance and a temperature coefficient.

According to some embodiments of the invention, the resistive properties of the first resistant element yield an essentially constant amplifier output level for an equal current through the shunt over a temperature range.

According to some embodiments of the invention, a reference resistance of the thermistor equals the product of the total resistance of the first resistant element at a reference temperature and the ratio of the respective temperature coefficients of the shunt and the thermistor.

According to an aspect of some embodiments of the present invention there is provided a method for measuring a current through a shunt, wherein the shunt has a resistance which varies with a temperature of the shunt. The method includes: outputting a shunt voltage signal through an output resistance which varies in accordance with a temperature of a predetermined location subject to thermal drift on the shunt, and amplifying the output voltage signal by a gain determined by the output resistance, such that a change in shunt temperature causes a compensating change in amplifier gain.

According to some embodiments of the invention, the method further includes selecting a thermal response of the resistance which yields an essentially constant amplifier output level for an equal current through the shunt over a temperature range.

According to an aspect of some embodiments of the present invention there is provided a method for providing a current measurement unit. The method includes: providing a current sensor having a shunt, a first terminal and a second terminal, and attaching a first resistant element between the shunt and the first terminal such that at least a portion of the first resistant element is in thermal contact with a first predetermined location subject to thermal drift on the shunt, wherein a resistance of the first resistant element varies in accordance with a temperature of the shunt, thereby to provide an output stabilized for changes in shunt temperature.

According to some embodiments of the invention, the method further includes attaching a second resistant element between the shunt and the second terminal such that at least a portion of the second resistant element is in thermal contact with a second predetermined location subject to thermal drift on the shunt, wherein a resistance of the second resistant element varies in accordance with a temperature of the shunt.

According to some embodiments of the invention, the method further includes connecting an amplifier circuit between the terminals.

According to some embodiments of the invention, the method further includes providing the first resistant element as a series combination of a thermistor and a fixed resistor.

According to some embodiments of the invention, a reference resistance of the thermistor equals the product of the total resistance of the resistant element and the ratio of the temperature coefficient between the first and second terminals and the temperature coefficient of the thermistor.

According to an aspect of some embodiments of the present invention there is provided a current measurement unit for providing an output for measuring the current through a shunt, wherein the shunt has a resistance which varies with a temperature of the shunt. The current measurement unit includes:

a controllable-gain amplifier, configured for amplifying an input signal with a gain determined by a gain control signal; and

a gain control element associated with the amplifier, in thermal contact with a location subject to thermal drift on the shunt, configured for providing a gain control signal to the amplifier in accordance with a temperature at the location such that a change in shunt temperature causes a compensating change in amplifier gain.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 illustrates a measurement shunt connected to an amplifier circuit;

FIG. 2A illustrates a shunt formed of Manganin strips between two brass mountings, and a simplified equivalent circuit diagram;

FIG. 2B is a simplified electrical circuit of a shunt connected to an amplifier circuit;

FIG. 3 is a simplified graph of the variation of shunt resistance, amplifier output level and amplifier gain, over a temperature range;

FIGS. 4A and 4B are simplified block diagrams of a current sensor, in accordance with a first and a second preferred embodiment of the present invention respectively;

FIG. 5 illustrates an exemplary current sensor with thermistors between the shunt's brass mountings and the terminals;

FIG. 6 shows the exemplary current sensor of FIG. 5 followed by an amplifier circuit;

FIGS. 7 and 8 are simplified block diagrams of a current measurement unit, according to a first and a second preferred embodiment of the present invention respectively;

FIG. 9 is a simplified circuit diagram of an exemplary shunt with associated thermistors;

FIG. 10 is a graph of the circuit gain K(t) and shunt resistance Rₛₕ(t) as a function of temperature;

FIG. 11 is a graph of the derivative of the amplifier output voltage with respect to temperature;

FIG. 12 is a simplified block diagram of a current measurement apparatus, according to a preferred embodiment of the present invention;

FIG. 13 is a simplified flowchart of a method for measuring a current through a shunt, according to a preferred embodiment of the present invention; and

FIG. 14 is a simplified flowchart of a method for providing a current measurement unit according to a preferred embodiment of the present invention.

### DESCRIPTION OF SPECIFIC EMBODIMENTS OF THE INVENTION

The present invention, in some embodiments thereof, relates to a shunt with a temperature-sensitive resistant element, and more particularly, but not exclusively, relates to current measurement through a shunt with compensation for temperature-related resistance changes.

Many applications require an accurate knowledge of the amount of current being carried through a current shunt. The current is evaluated by measuring the voltage drop across the shunt, and dividing the measured voltage by a known shunt resistance. However if the shunt resistance varies with temperature, the voltage measurement will not provide an accurate measure of the current through the shunt.

In order to compensate for the temperature-related changes in the voltage drop over the shunt, in some of the following embodiments a temperature-sensitive resistant element (such as a thermistor) is attached to the shunt. Changes in the resistance of the resistant element effectively control the gain of an amplifier connected to the shunt. The properties of the resistant element are selected so that the amplifier gain is adjusted for the shunt temperature, in a manner which cancels out the effects of the shunt's changing resistance. In this manner the relationship between the current through the shunt and the amplifier output level is stabilized, and variations due to changes is shunt temperature are reduced or eliminated.

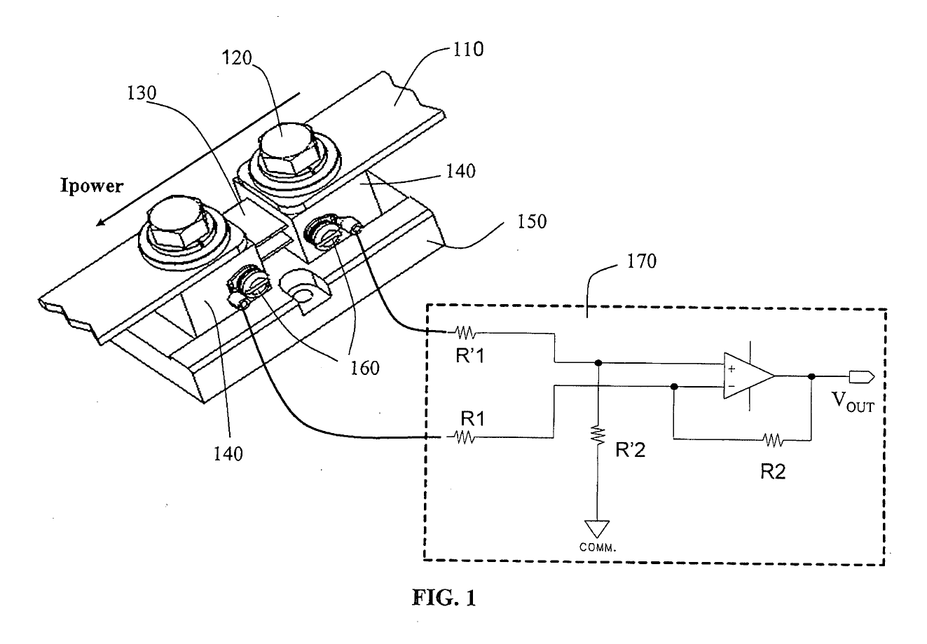

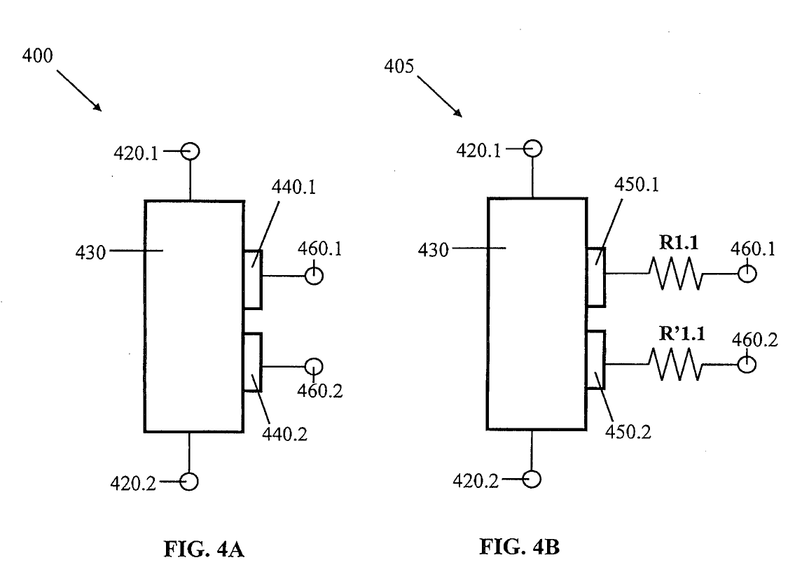

For purposes of better understanding some embodiments of the present invention, as illustrated in FIGS. 4a-14 of the drawings, reference is first made to the construction and operation of a typical shunt as illustrated in FIG. 1

FIG. 1 shows a measurement shunt connected to an amplifier circuit 170. The current through the shunt is reflected in the amplifier output voltage. The shunt includes Manganin strips 130, which are linked to terminals 160 via brass mountings 140. The shunt terminals 160 are connected to amplifier circuit 170, which amplifies the voltage drop over the shunt. It has been found that although the temperature coefficient of Manganin α_{M} is approximately 15 ppm/C.°, the total temperature drift of the shunt, α_{SH}, may be as much as 150 ppm/C.° due to the presence of the brass mountings 140.

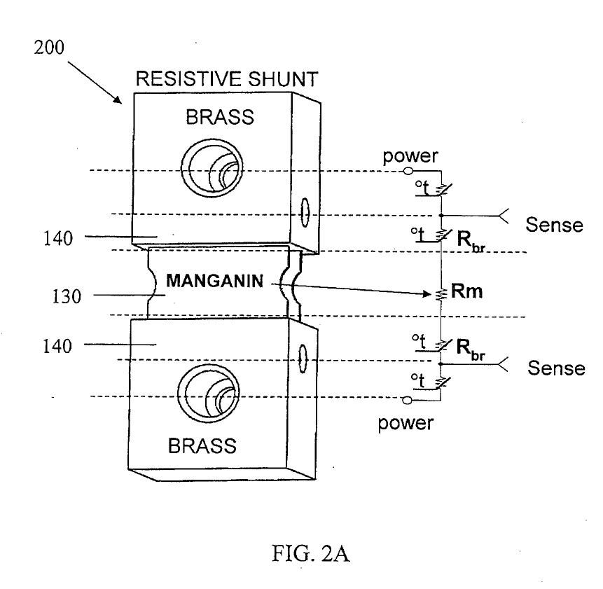

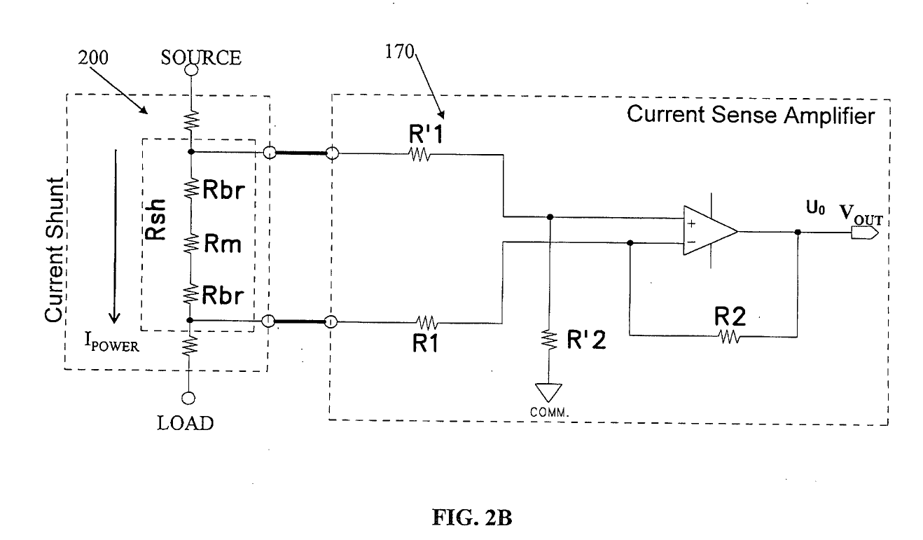

Reference is now made to FIG. 2B which illustrates a shunt 200 which includes Manganin strips 130 between two brass mountings 140, and a simplified equivalent circuit of shunt 200. It is seen that the resistance of the brass portions of the shunt contribute to the total shunt resistance.

In the following, the term “amplifier circuit” includes any circuit and/or device which amplify an input voltage. The amplifier circuit may include an amplifying element (such as an operational amplifier) with associated circuitry (such as resistors configured to form the required input and output paths and to provide the desired amplifier gain). Some examples and embodiments below utilize a differential amplifier circuit configuration. However other embodiments may use other amplifying elements and/or amplifier circuit configurations, which are hereby included in the scope of the present embodiments.

Reference is now made to FIG. 2B, which is a simplified electrical circuit diagram showing shunt 200 connected to an amplifier circuit 170. The current over shunt 200, I_{power}, is reflected in the amplifier output voltage Uₒᵤₜ. If R1=R′1 and R2=R′2, the gain of amplifier circuit 170 is:

$${k}_{A} = \frac{{R}_{2}}{{R}_{1}} \qquad ( 1 )$$

The voltage drop over the shunt, U_{SH}, is:

V_{SH}=I_{power}×R_{SH} (2)

where I_{power} is the current through the shunt and R_{SH} is the shunt resistance. The amplifier output voltage, V_{OUT}, is:

$${V}_{OUT} = {V}_{SH} \times {k}_{A} = {I}_{power} \times {R}_{SH} \times \frac{{R}_{2}}{{R}_{1}} \qquad ( 3 )$$

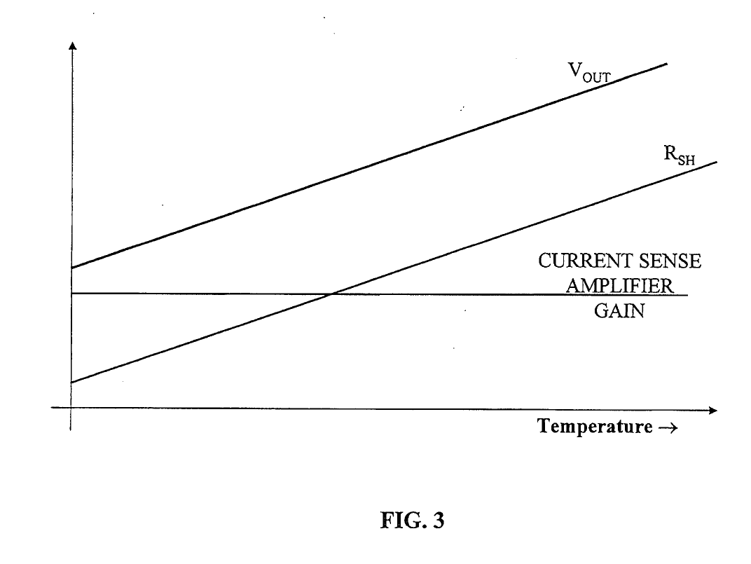

It is seen that given a fixed (i.e. non-variable) R₁ and R₂, variations in the shunt resistance R_{SH} lead to changes in the shunt output voltage even when the current I_{power} is constant, as shown schematically in FIG. 3. This leads to a lack of accuracy in the current measurement.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

In order to compensate for temperature-related variations in the shunt resistance R_{SH}, some embodiments of the present invention include a resistant element, such as a thermistor, whose resistance varies with temperature in a known manner.

The properties of the resistant element are selected in order to compensate for variations in the shunt resistance, as described more fully below.

Reference is now made to FIG. 4A, which is a simplified block diagram of a shunt in accordance with a first preferred embodiment of the present invention.

Current sensor 400 includes a shunt 430, which carries the current between the two input terminals 420.1 and 420.2. The current through the shunt may be determined from the measured voltage drop through the shunt, between output terminals 460.1 and 460.2. Current sensor 400 also includes at least one resistant element 440.1 which is electrically connected between the shunt 430 and terminal 460.1. Resistant element 440.1 preferably includes a thermistor, which is physically located on the shunt so as to be in thermal contact with a predetermined location on the shunt which is subject to thermal drift, and a fixed resistor in series with the thermistor. Resistant element 440.1 thus has a resistance which varies in accordance with the shunt temperature, as reflected by the temperature of the location to which it is coupled. In the preferred embodiment, current sensor 400 includes a second resistant element 440.2 which has a resistance which varies in accordance with the shunt temperature, and is electrically located between the shunt 430 and terminal 460.2. Similarly to resistant element 440.1, resistant element 440.2 preferably includes a thermistor, which is connected to the shunt so as to be in thermal contact with a second predetermined location on the shunt which is subject to thermal drift, and a series fixed resistor.

FIG. 4B is a simplified block diagram of a current sensor in which both of the resistant elements are formed as a series combination of a thermistor (in thermal contact with shunt 430) and a fixed resistor. The resistor values R1.1 and R′1.1, together with those of serial thermistors 440.1 and 440.2, are selected to obtain the desired variation of resistance with the shunt temperature.

Preferably current sensor 400 is configured for connection to an amplifier, so that the resistant element forms part of the input path into the amplifier. In some embodiments a feedback amplifier may be connected to output terminals 460.1 and 460. When the amplifier has a gain which varies in accordance with the input resistance, such as in differential amplifier circuit 170, variations in the resistance of the resistant element control the amplification of the voltage signal measured across the shunt terminals.

In the preferred embodiment, the resistive properties of one or both resistant elements compensate, at least in part, for the variations in the voltage drop between terminals 460.1 and 460.2 due to changes in shunt temperature. The resistive properties are selected so that, for a given current through the shunt, the amplification rises as the voltage drop through the shunt decreases and vice versa. The term “resistive properties” refers to the thermistor's reference resistance and thermal coefficient, and, when the resistant element includes a fixed resistor, the value of the fixed resistance.

Including a fixed resistor in the resistant element (or elements) leads to a more flexible selection of the resistant element's resistive properties, as may be seen in Eqn. 15 below. For example, a thermistor which is convenient to attach to the shunt may be used, and the desired overall performance obtained by proper selection of the fixed resistor value.

In some embodiments, one or both resistant elements 440.1 and 440.2 are thermally coupled to shunt 430, so that the thermistor temperature is substantially equal to the temperature of shunt 430. The thermistor resistance is thus directly affected by the shunt temperature. In a preferred embodiment the one or both resistant elements 440.1 and 440.2 are thermally coupled to a portion of the shunt which has a relatively large temperature coefficient, for example the shunt mounting. Note that when a resistant element includes a fixed resistor, the fixed resistor may not be thermally connected to the shunt since its resistance does not vary significantly with temperature, so that only a portion of the resistant element is thermally coupled to the shunt.

In a first exemplary embodiment, the properties of one or both resistant elements are selected to provide complete compensation for the thermal drift of the shunt resistance, as described above. The term “complete compensation” indicates that the relationship between the current through the shunt and the amplifier circuit output level is essentially the same over a temperature range. In some embodiments the output level is considered to be essentially at the same level if it is within a specified output range. Typically, the temperature range is a specified range over temperatures of interest for the shunt operation. The thermistor properties typically include the reference resistance and the thermistor temperature coefficient. In a second exemplary embodiment the thermistor properties are selected to yield the same amplifier output at two specified temperatures.

Preferably, the reference resistance of the thermistor equals the product of the total resistance between the shunt and an amplifier input, and the ratio of the respective temperature coefficients of the shunt and the thermistor (see Eqn. 15 below). In some embodiments the temperature coefficient of the shunt is taken as a portion of the shunt's total temperature coefficient between input terminals 420.1 and 420.2, depending on the location of one or both thermistors.

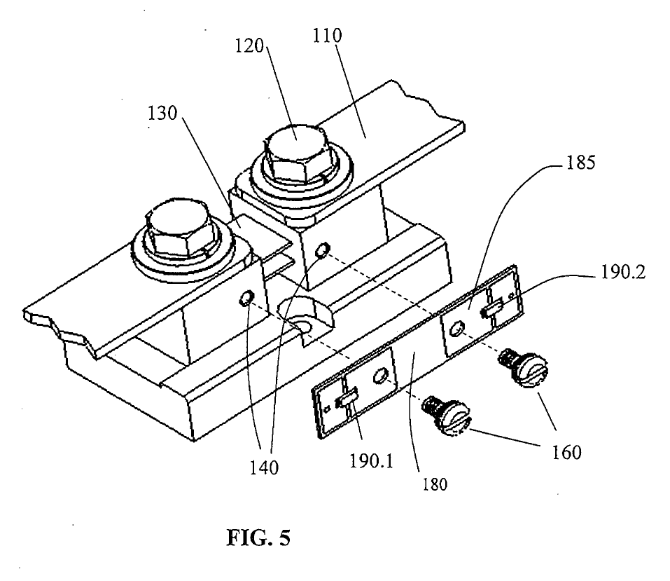

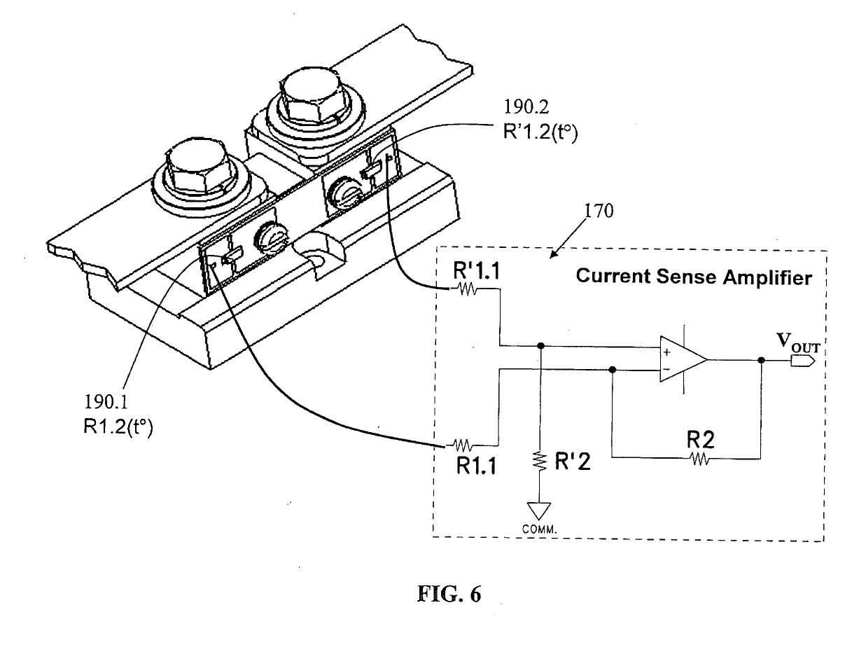

FIG. 5 illustrates an exemplary current sensor with thermistors between the brass mountings 140 and terminals 160. Thermistors 190.1 and 190.2 are attached to electrically isolated plate 180. Plate 180 is screwed on to the shunt body so that the thermistor temperature follows the shunt temperature. FIG. 6 shows the exemplary current sensor of FIG. 5 followed by amplifier circuit 170. Thermistors 190.1 and 190.2 connect between shunt and amplifier 170, effectively forming part of the input path into amplifier circuit 170.

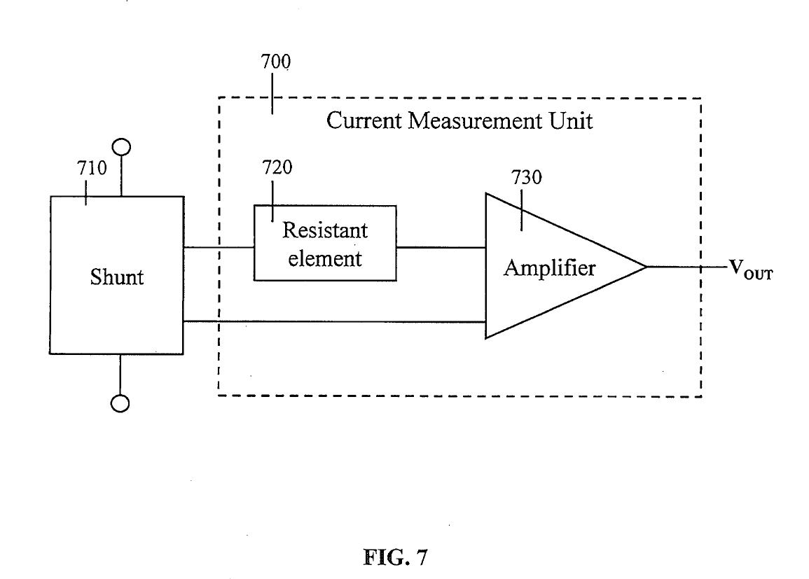

Reference is now made to FIG. 7, which is a simplified block diagram of a current measurement unit, according to a first preferred embodiment of the present invention. Shunt 710 has a resistance which varies with the shunt temperature. Current measurement unit 700 includes resistant element 720 and amplifier 730.

The amplifier circuit output level reflects the current through shunt 710. In the preferred embodiments the amplifier circuit output is a voltage, whose level reflects the current through the shunt. An analysis of the performance of an amplifier circuit with two resistant elements (see FIG. 8) is presented below.

Amplifier 730 amplifies the voltage drop across all or a portion of shunt 710, depending on the location of the shunt's output terminals on the shunt. The amplifier gain is determined, at least in part, by the resistance between shunt 710 and amplifier 730. For example, in the differential amplifier circuit of FIG. 1, the gain is given by the ratio R₂/R₁ (when R′₁=R₁ and R′₂=R₂). Thus the amplifier gain may be controlled by varying R₁.

Resistant element 720 provides a resistance between one terminal of shunt 710 and one input of amplifier 730. In the preferred embodiment resistant element 720, or a thermally-sensitive portion of resistant element 720, is structured to be thermally-coupled to a predetermined location on the shunt, for example by mounting resistant element 720 onto a plate which attaches to the shunt mountings. In some embodiments, the second terminal of shunt 710 is connected directly to the second amplifier input. In other embodiments, current measurement unit 700 further includes a resistor between the second terminal of shunt 720 and the second amplifier input (not shown). The connection of resistant element 720, and of the fixed resistor when present, between the shunt terminals and the amplifier inputs results in the amplification of the voltage drop between the shunt terminals by voltage amplifier 730.

The resistance of resistant element 720 varies in accordance with the shunt temperature, resulting in changes to the amplifier gain. The properties of resistant element 720 are selected so that a change in shunt resistance causes a compensating change in amplifier gain. For example, if the shunt resistance drops (and the voltage across the shunt is consequently reduced) the amplifier gain is increased, thereby reducing or eliminating the drop in the amplifier output level. Thus the amplifier output level may remain constant for a given current through the shunt despite changes in the shunt temperature (or over a specified range).

In an exemplary embodiment, resistant element 720 includes a fixed resistor R_{1.1} and a thermistor R_{1.2}(t°). The term “fixed resistor” indicates a resistor with a constant resistance value. The thermistor is preferably physically attached to shunt 710, so that the thermistor temperature is close to or equal to the shunt temperature.

The resistant element may be connected between the shunt and an amplifier inverting input or non-inverting input, depending on the amplifier circuit configuration.

Reference is now made to FIG. 8, which is a simplified block diagram of a current measurement unit, according to a second preferred embodiment of the present invention. In the present embodiment, two resistant elements, 820.1 and 820.2 (one of which is also connected to a feedback resistance), are connected between the shunt terminals and the amplifier non-inverting and inverting inputs respectively. The two resistant elements may have the same properties (e.g. fixed resistance, reference resistance and/or thermal coefficient), or may have different properties. A feedback resistor 840 is typically connected between the amplifier output and the amplifier inverting input.

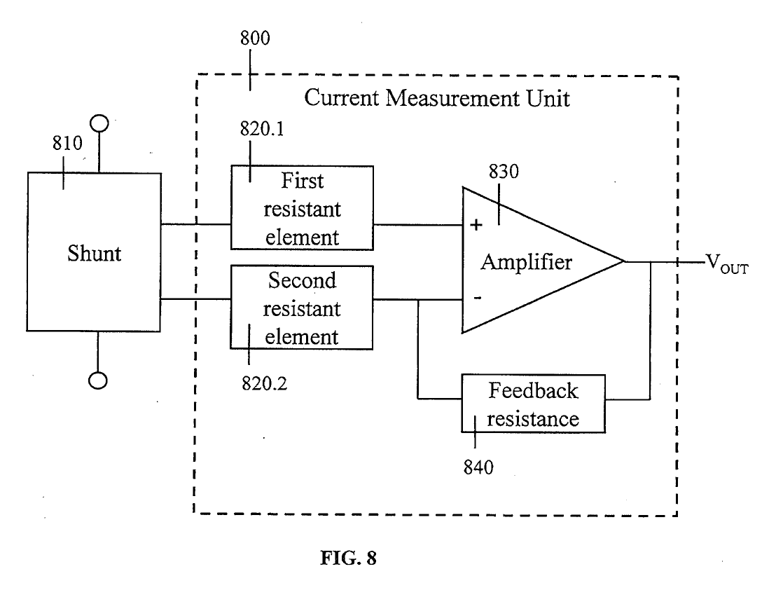

FIG. 9 is a simplified circuit diagram of an exemplary shunt 900 with associated thermistors, R1.2(t°) and R′1.2(t°), followed by amplifier circuit 910. In the present embodiment, the amplifier circuit includes a voltage divider to each input of a differential amplifier. Resistant elements, R₁(t) and R′₁(t), are placed between each shunt terminal and the respective differential amplifier input. Amplifier circuit 910 includes fixed feedback resistors R1.1 and R2.

The following presents a simplified analysis of the circuit performance.

In the embodiment of FIG. 9, resistant elements R₁(t) and R′₁(t) are shown as being part of the shunt, whereas fixed resistances R1.1 and R′1.1 are shown as part of the amplifier circuit. FIG. 9 is a non-limiting exemplary circuit configuration for analysis purposes. Other embodiments may apportion the resistances between the circuit components in different manners.

Given a shunt with a voltage drop of V₀ₛₕ at the reference temperature T₀ for a current through the shunt of I₀, the reference shunt resistance, R₀ₛₕ, equals:

$${R}_{0 sh} = \frac{{V}_{0 sh}}{{I}_{0}} \qquad ( 4 )$$

The shunt resistance varies with shunt temperature as:

Rₛₕ(t)=R₀ₛₕ(t)·[1+α_{sh.i}(t−T₀)] (5)

where α_{sh.i} is the shunt resistance temperature coefficient between the two shunt terminals.
The thermistor resistance equals:

R_{1.2}(t)=R_{1.2}[1+αₜᵣ(t−T₀)]. (6)

where αₜᵣ is the thermistor temperature coefficient. The thermal behavior of the total resistance between the shunt and the amplifier input is:

R₁(t)=R_{1.1}+R_{1.2}[1+αₜᵣ(t−T_{0.c})] (7)

Assume that the errorless amplifier gain is K₀ at temperature T_{O}. K₀ equals:

$${K}_{0} = \frac{{V}_{out}}{{R}_{0 sh} \cdot I} \to \frac{{I}_{0} \cdot {V}_{out}}{I \cdot {V}_{0 sh}} \qquad ( 8 )$$

where I is the actual current through the shunt. This gives a total input resistance, R₁, of:

$${R}_{1} = \frac{{R}_{2}}{{K}_{0}} \to \frac{I \cdot {V}_{0 sh} \cdot {R}_{2}}{{I}_{0} \cdot {V}_{out}} \qquad ( 9 )$$

It is desired that for a given level of current through the shunt, the amplifier output voltage, V_{OUT}, should remain the same regardless of the shunt temperature.

Referring now to the amplifier circuit of FIG. 9, resistors R′₁(t) and R′₂(t) serve as a voltage divider which scales the voltage into the non-inverting amplifier input by a factor of:

$${K}_{d} ( t ) = \frac{{R}^{′} 2}{{R}_{1}^{′} ( t ) + {R}^{′} 2} \qquad ( 10 )$$

The non-inverting amplifier gain equals:

$${K}_{1} ( t ) = 1 + \frac{R 2}{{R}_{1} ( t )} \qquad ( 11 )$$

The actual circuit gain at the amplifier output (V_{OUT}) is the product:

When R′₁(t)=R₁(t) and R′₂=R₂, the actual circuit gain equals:

$${K}_{1} ( t ) = ( 1 + \frac{R 2}{{R}_{1} ( t )} ) \cdot ( \frac{R 2}{{R}_{1} ( t ) + R 2} ) \qquad ( 13 )$$

and the amplifier output voltage is:

V_{OUT}(t)=I×Rₛₕ(t)×K(t) (14)

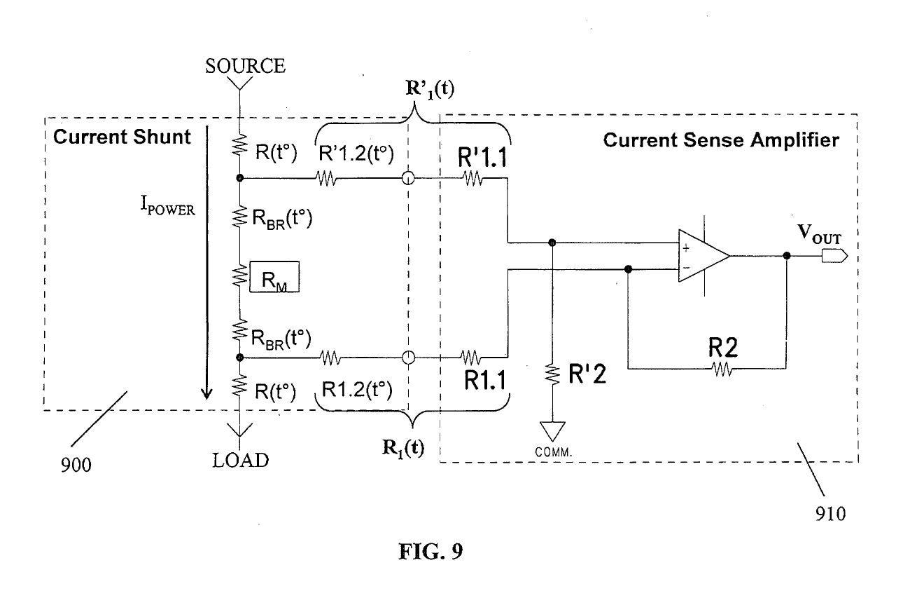

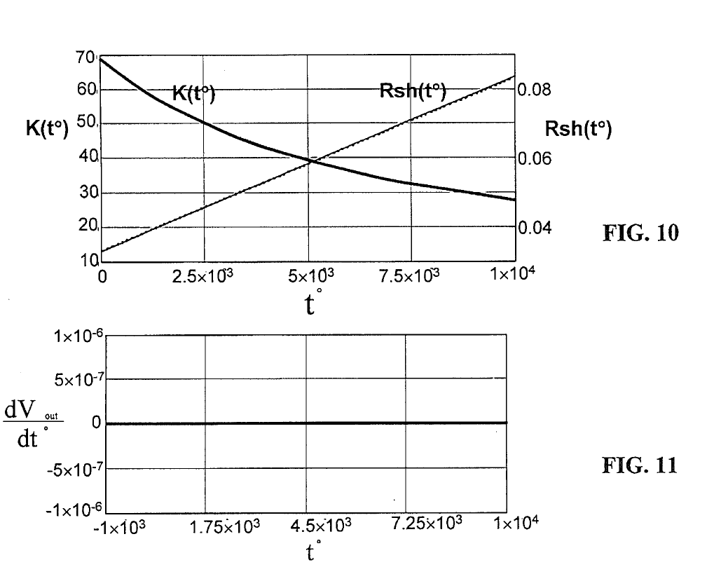

FIGS. 10 and 11 present the results of a MathCad simulation of the above equations, when the thermistor value is selected as:

$${R}_{1.2} = {R}_{1} \frac{{α}_{sh . i}}{{α}_{tr}} \qquad ( 15 )$$

FIG. 10 shows the actual circuit gain K(t) and shunt resistance Rₛₕ(t) as a function of temperature (solid and dotted lines respectively). It is seen that gain K(t) increases linearly with temperature, whereas the shunt resistance Rₛₕ(t) decreases with temperature.

FIG. 11 shows the derivative of the amplifier output voltage with respect to temperature,

$$\frac{d {V}_{OUT}}{d t} ,$$

for a constant current through the shunt (heavy solid line). The derivative equals zero over a wide range of temperatures (from −1000° C. to 10,000° C.). The amplifier output voltage is thus seen to be constant over a wide temperature range for a constant current.

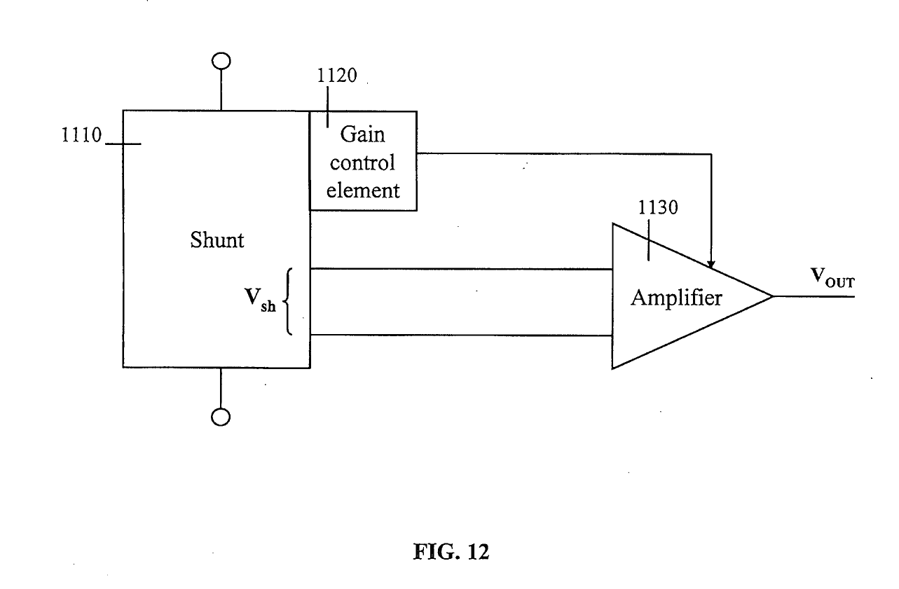

Reference is now made to FIG. 12, which is a simplified block diagram of a current measurement apparatus, according to a preferred embodiment of the present invention. Gain control element 1120 is thermally coupled to a location on shunt 1110, so that the temperature of gain control element 1120 follows the shunt temperature. Amplifier 1130 is a controllable amplifier, whose gain is adjusted by an external control signal. Based on its own temperature, gain control element 1120 generates a control signal for amplifier 1130, thus effectively controlling the amplifier gain in accordance with the shunt temperature. Preferably the control signal compensates, at least in part, for changes in the voltage across shunt 1110 due to changes in shunt temperature. Thus a constant (or near constant) relationship may be maintained between the output voltage V_{OUT} and the current through shunt 1110, regardless of shunt temperature (or while the shunt temperature remains within a temperature range).

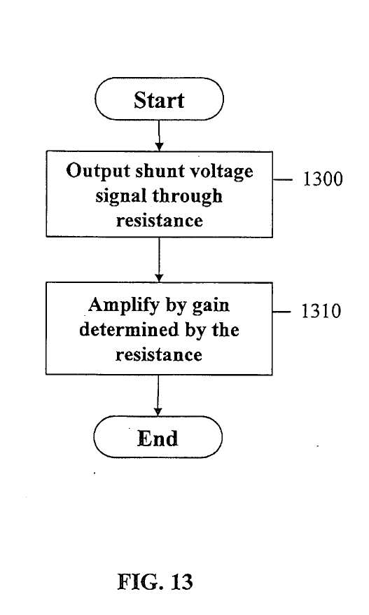

Reference is now made to FIG. 13, which is a simplified flowchart of a method for measuring a current through a shunt, according to a preferred embodiment of the present invention. The shunt has a resistance which varies with a temperature of the shunt, as discussed above.

In 1300, the shunt voltage is output through a resistance which varies in accordance with the temperature of a predetermined location on the shunt, where the location is subject to thermal drift. In 1310, the output voltage signal is amplified by a gain determined by the output resistance, such that a change in shunt temperature (as reflected by the temperature of the predetermined location) causes a compensating change in amplifier gain. The thermal response of the output resistance preferably yields an essentially constant amplifier output level for an equal current through the shunt, over a temperature range.

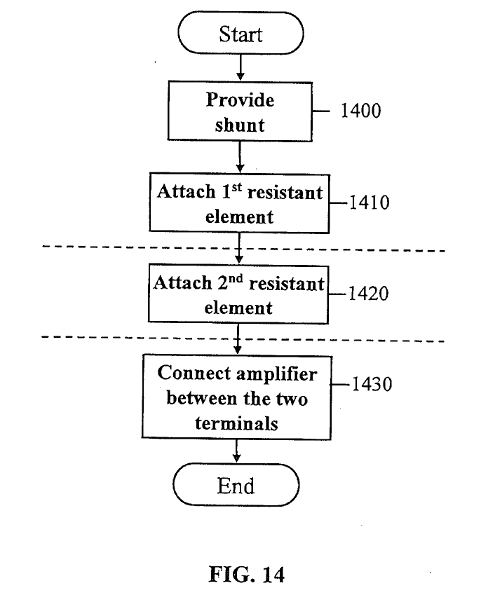

Reference is now made to FIG. 14, which is a simplified flowchart of a method for providing a current measurement unit according to a preferred embodiment of the present invention.

In 1400 a current sensor with a shunt and two terminals is provided. The two terminals enable measuring a voltage drop through the shunt.

In 1410 a resistant element is attached between the shunt and a first terminal. The attachment is performed in a manner such that the resistant element has a resistance which varies in accordance with a temperature of the shunt. The resistant element is attached to the shunt in a manner that ensures that at least a portion of the resistant element is in thermal contact with a predetermined location on the shunt which is subject to thermal drift. Preferably the resistant element maintains a temperature substantially equal to the temperature of the shunt. The term “substantially equal” means that the temperature of the resistant element tracks the shunt temperature closely enough to provide adequate compensation for the temperature-related changes in the shunt voltage. The resistant element, or a portion thereof, may be screwed on to the shunt, glued on to the shunt or connected to a plate or other mounting which is physically attached to the shunt.

Some embodiments include the further step of providing the resistant element as a series combination of a thermistor and a fixed resistor. Preferably the thermistor is affixed to the shunt, so that its temperature tracks the shunt temperature. In some embodiments the thermistor resistance equals

$${R}_{1} \frac{{α}_{sh . i}}{{α}_{tr}} ,$$

as described above.

Some embodiments further include attaching a second resistant element between the shunt and the second terminal 1420, so that the second resistant element is thermally coupled to a second predetermined location subject to thermal drift on the shunt. Some embodiments include the further step of providing the second resistant element as a series combination of a thermistor and a fixed resistor. Preferably the thermistor is affixed to the shunt, so that its temperature tracks the shunt temperature.

Some embodiments further include connecting an amplifier between the two terminals 1430. In some embodiments, the amplifier is configured as a difference amplifier, preferably having a gain dependent on the resistance between the shunt and one or both of the amplifier inputs.

The method may include the providing and/or connecting additional electronic components, in order to provide a required amplifier circuit configuration. For example, a feedback resistor may be connected between the amplifier output and the amplifier inverting input.

Embodiments described above utilize a resistant element having a temperature-sensitive resistance, such as a thermistor, to automatically adjust the amplifier gain to compensate for changes in the shunt resistance. A simple differential amplifier configuration may thus be used to amplify the voltage drop across the shunt, while still obtaining the same output level for a given current through the shunt regardless of shunt temperature. Thus highly accurate measurements of the current may be obtained with an easily implemented circuit configuration.

It is expected that during the life of a patent maturing from this application many relevant shunts, resistors, thermistors, amplifiers and amplifier circuit configurations will be developed and the scope of the term shunt, resistor, thermistor, amplifier and amplifier circuit is intended to include all such new technologies a priori.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A current sensor, comprising:
a shunt, configured for conveying an electric current, and having a resistance which varies with a temperature of said shunt;
a first resistant element connected between said shunt and a first output terminal, at least a portion of said first resistant element being in thermal contact with a first predetermined location subject to thermal drift on said shunt, and having a resistance which varies in accordance with a temperature of said shunt, such that a change in the resistance of said shunt causes a compensating change in the gain of an associated amplifier; and
a second output terminal, said first and second output terminals being configured for measurement of a voltage over said shunt.

2. A current sensor according to claim 1, wherein said first resistant element comprises a first fixed resistor and a first thermistor in series.

3. A current sensor according to claim 2, wherein a reference resistance of said first thermistor comprises the product of the total resistance between said shunt and an amplifier input at a reference temperature, and the ratio of the temperature coefficient between said first and second output terminals and the temperature coefficient of said thermistor.

4. A current sensor according to claim 2, wherein the resistive properties of said first thermistor are selected so as yield an essentially constant output level from an amplifier circuit connected across said shunt output terminals, for an equal current through said shunt over a temperature range.

5. A current sensor according to claim 2, wherein the resistive properties of said first thermistor are selected so as yield an essentially constant output level from an amplifier circuit connected across said shunt terminals, for an equal current through said shunt for at least two specified temperatures.

6. A current sensor according to claim 2, further comprising a second resistant element connected between said shunt and said second terminal, at least a portion of said second resistant element being in thermal contact with a second predetermined location subject to thermal drift on said shunt, and having a resistance which varies in accordance with a temperature of said shunt.

7. A current sensor according to claim 6, wherein said second resistant element comprises a second fixed resistor and a second thermistor in series.

8. A current sensor according to claim 1, wherein said first predetermined location is located on a shunt mounting.

9. A current sensor according to claim 4, wherein said resistive properties comprise at least one of: a reference resistance, a temperature coefficient of said thermistor, and a value of said fixed resistor.

10. A current measurement unit, for providing an output for measuring the current through a shunt, wherein said shunt has a resistance which varies with a temperature of said shunt, comprising:
an amplifier, configured for amplifying a voltage drop across said shunt, and having a gain determined by a total resistance between said shunt and said amplifier; and
a first resistant element connected between said shunt and a first amplifier input, in thermal contact with a first predetermined location subject to thermal drift on said shunt, and having a resistance which varies in accordance with said temperature of said shunt, such that a change in shunt resistance causes a compensating change in amplifier gain.

11. A current measurement unit according to claim 10, further comprising a second resistant element connected between said shunt and a second amplifier input, in thermal contact with a second predetermined location subject to thermal drift on said shunt, wherein a resistance of said second resistant element varies in accordance with said temperature of said shunt.

12. A current measurement unit according to claim 10, wherein said first resistant element comprises a thermistor.

13. A current measurement unit according to claim 10, wherein said first resistant element further comprises a fixed resistor.

14. A current measurement unit according to claim 12, wherein said first predetermined location is located on a shunt mounting.

15. A current measurement unit according to claim 11, wherein the resistive properties of said first resistant element yield an essentially constant amplifier output level for an equal current through said shunt for at least two specified temperatures.

16. A current measurement unit according to claim 15, wherein said resistive properties comprise at least one of a reference resistance and a temperature coefficient.

17. A current measurement unit according to claim 11, wherein the resistive properties of said first resistant element yield an essentially constant amplifier output level for an equal current through said shunt over a temperature range.

18. An current measurement unit according to claim 12, wherein a reference resistance of said thermistor comprises the product of the total resistance of said first resistant element at a reference temperature and the ratio of the respective temperature coefficients of said shunt and said thermistor.

19. A method for measuring a current through a shunt, wherein said shunt has a resistance which varies with a temperature of said shunt, comprising:
outputting a shunt voltage signal through an output resistance which varies in accordance with a temperature of a predetermined location subject to thermal drift on said shunt; and
amplifying said output voltage signal by a gain determined by said output resistance, such that a change in shunt temperature causes a compensating change in amplifier gain.

20. A method according to claim 19, further comprising selecting a thermal response of said resistance which yields an essentially constant amplifier output level for an equal current through said shunt over a temperature range.

21. A method for providing a current measurement unit comprising:
providing a current sensor having a shunt, a first terminal and a second terminal; and
attaching a first resistant element between said shunt and said first terminal such that at least a portion of said first resistant element is in thermal contact with a first predetermined location subject to thermal drift on said shunt, wherein a resistance of said first resistant element varies in accordance with a temperature of said shunt, thereby to provide an output stabilized for changes in shunt temperature.

22. A method according to claim 21, further comprising attaching a second resistant element between said shunt and said second terminal such that at least a portion of said second resistant element is in thermal contact with a second predetermined location subject to thermal drift on said shunt, wherein a resistance of said second resistant element varies in accordance with a temperature of said shunt.

23. A method according to claim 22, further comprising connecting an amplifier circuit between said terminals.

24. A method according to claim 21, further comprising providing said first resistant element as a series combination of a thermistor and a fixed resistor.

25. A method according to claim 24, wherein a reference resistance of said thermistor comprises the product of the total resistance of said resistant element and the ratio of the temperature coefficient between said first and second terminals and the temperature coefficient of said thermistor.

26. A current measurement unit for providing an output for measuring the current through a shunt, wherein said shunt has a resistance which varies with a temperature of said shunt, comprising:
a controllable-gain amplifier, configured for amplifying an input signal with a gain determined by a gain control signal; and
a gain control element associated with said amplifier, in thermal contact with a location subject to thermal drift on said shunt, configured for providing a gain control signal to said amplifier in accordance with a temperature at said location such that a change in shunt temperature causes a compensating change in amplifier gain.
